(19) United States
(12) Patent Application Publication
(10) Pub. No.: US 2007/0096272 A1
(43) Pub. Date: May 3, 2007

(54) Light emitting diode package

(76) Inventor: Jiun-Heng Wang, Tainan County (TW)

Correspondence Address: J.C. Patents, Inc., Suite 250, 4 Venture, Irvine, CA, 92618, US

(21) Appl. No.: 11/433,150

(22) Filed: May 12, 2006

(30) Foreign Application Priority Data
Oct. 28, 2005 (TW) 94137764

(51) Int. Cl. H01L 23/495

(52) U.S. Cl. 257/675

(57) ABSTRACT

A LED package includes a LED chip and a flexible carrier, wherein the LED chip has a plurality of electrodes. The flexible carrier has a flexible substrate and a circuit layer, wherein the flexible substrate has a support surface and a back surface opposite the support surface, and the circuit layer is disposed on the support surface. In addition, the LED package further includes a plurality of bumps and the electrodes of the LED chip are electrically connected to the circuit layer of the flexible carrier through the bumps.

### CROSS-REFERENCE TO RELATED APPLICATION

This application claims the priority benefit of Taiwan application serial no. 094137764, filed on Oct. 28, 2005. All disclosure of the Taiwan application is incorporated herein by reference.

### BACKGROUND OF THE INVENTION

1. Field of Invention

The present invention relates to a semiconductor package, and particularly to a light emitting diode package (LED package).

2. Description of the Related Art

A light emitting diode (LED) formed by semiconductor material made of the compound of the group III-V elements is a broad band-gap luminous component, which emits lights from infrared light to ultraviolet light, including all wavebands of visible light. In recent years, along with the rapid progress in high-brightness gallium nitride (GaN) LED producing blue/green light, full-color LED displays, white LEDs and LED traffic lights have gained feasible applications, while other kinds of LEDs have also got popular applications in various fields.

A LED chip includes a P-type epitaxial layer, an N-type epitaxial layer and an active layer therebetween, namely a luminous layer, wherein the P-type epitaxial layer and the N-type epitaxial layer are made of the compound of the group III-V elements. The luminous efficiency of a LED depends on the internal quantum efficiency of the active layer thereof and the light extraction efficiency thereof. The internal quantum efficiency can be enhanced mainly by improving the epitaxial growing quality of the active layer and the structure design of the epitaxial layer thereof, and the key to enhance the light extraction efficiency is to reduce the energy loss of the light transmitted from the active layer while the light is reflected inside the LED.

A conventional LED package includes a carrier and a LED chip, wherein the carrier includes a substrate and a circuit layer and the material of the substrate is aluminum nitride or silicon nitride, which means the carrier is a rigid carrier. In the prior art, the LED chip is electrically connected to the circuit layer on the carrier through bumps.

Note that, when a plurality of LED chips are packed on a single carrier, since the carrier in the LED package is a rigid carrier, or the carrier is not flexible, the useable space of the conventional LED package is limited. Thus, how to make a LED package flexible for increasing the useable space thereof to adapt the compactness trend of modern electronic products is an important issue.

### SUMMARY OF THE INVENTION

Accordingly, the present invention is directed to provide a LED package having a flexible carrier.

As embodied and broadly described herein, the present invention provides a LED package including a LED chip and a flexible carrier. The LED chip has a plurality of electrodes. The flexible carrier has a flexible substrate and a circuit layer, wherein the flexible substrate has a support surface and a back surface opposite to the support surface, while the circuit layer is disposed on the support surface. In addition, the electrodes of the LED chip are electrically connected to the circuit layer of the flexible carrier.

In an embodiment of the present invention, the flexible carrier further includes a solder mask layer disposed on the circuit layer, and the solder mask layer exposes the circuit layer electrically connected to the electrodes.

In an embodiment of the present invention, the LED package further includes a plurality of bumps disposed on the electrodes, wherein the circuit layer is electrically connected to the electrodes through the bumps. Besides, the bump may be a gold bump, a copper bump, a nickel bump or an aluminum bump.

In an embodiment of the present invention, the material of the bump can be conductive B-stage adhesive.

In an embodiment of the present invention, the LED package further includes a plurality of conductive materials, wherein each conductive material is disposed between the circuit layer and each bump such that the circuit layer is electrically connected to every bump through the conductive materials. The material of the conductive material can be, for example, solder, conductive B-stage adhesive, anisotropic conductive film (ACF), or anisotropic conductive paste (ACP).

In an embodiment of the present invention, the flexible carrier is, for example, a flexible printed circuit board (FPCB), while the material of the flexible substrate is, for example, polyimide (PI).

In an embodiment of the present invention, the LED package further includes a heat sink adhered to the back surface of the flexible substrate. In addition, the flexible substrate has a plurality of thermal vias filled with metal and the thermal vias are located in the area covered by the heat sink.

In an embodiment of the present invention, the material of the circuit layer is, for example, copper.

Based on the above described, the LED package in the present invention features a flexible carrier therein, which enables the LED package to possess yieldingness, therefore the usage flexibility of the LED package in various spaces is enhanced.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve for explaining the principles of the invention.

FIG. 1 is a diagram of a LED package provided by the first embodiment of the present invention.

FIG. 2 is a diagram of a LED package provided by the second embodiment of the present invention.

### DESCRIPTION OF THE EMBODIMENTS

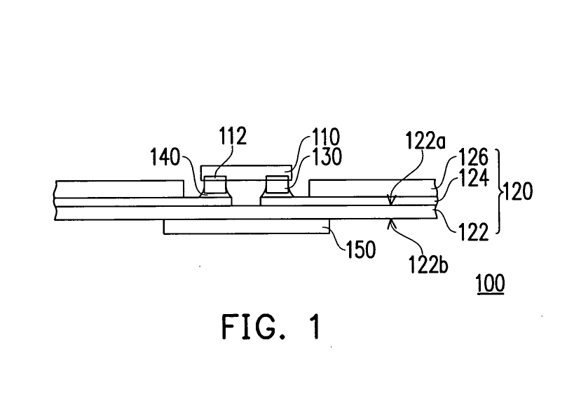

FIG. 1 is a diagram of a LED package provided by the first embodiment of the present invention. It can be seen from FIG. 1 that the LED package 100 of the present embodiment includes a LED chip 110 and a flexible carrier 120, wherein the LED chip 110 has a plurality of electrodes 112. The flexible carrier 120 has a flexible substrate 122 and a circuit layer 124, the flexible substrate 122 has a support surface 122a and a back surface 122b opposite the support surface 122a, and the circuit layer 124 is disposed on the support surface 122a.

On the other hand, the LED package 100 further includes a plurality of bumps 130, wherein the bumps 130 are disposed on the electrodes 112, while the circuit layer 124 is electrically connected to the electrodes 112 through the bumps 130. Herein, the bump 130 is, for example, a gold bump, a copper bump, a nickel bump or an aluminum bump and the material of the circuit layer 124 is, for example, copper. In the embodiment, the flexible carrier 120 can further include a solder mask layer 126, which is disposed on the circuit layer 124 and exposes a portion of the circuit layer 124 that is electrically connected to the electrodes 112.

The flexible carrier 120 is explained in more detail hereinafter. In the embodiment, the flexible carrier 120 is, for example, a flexible printed circuit board (FPCB), while the material of the flexible substrate 122 of the flexible carrier 120 is, for example, polyimide (PI). Thus, the LED chip 110 can be disposed on the flexible carrier 120 by flip chip packaging technology and the LED package 100 consequently possesses good yieldingness, which can improve the usage flexibility of the LED package 100 in various spaces.

Accordingly, to get a good electrical connection between the bumps 130 and the circuit layer 124, the LED package 100 further includes a plurality of conductive materials 140, wherein the conductive materials 140 are disposed between the circuit layer 124 and the bumps 130. In this way, the circuit layer 124 is electrically connected to the bumps 130 through the conductive materials 140 stably and easily. The method for electrically connecting the conductive materials 140 to the bumps 130 can be performed by heat pressing and bonding. The material of the conductive material 140 can be, for example, solder, conductive B-stage adhesive, anisotropic conductive film (ACF) or anisotropic conductive paste (ACP).

The bump may be directly made of conductive B-stage adhesive, which makes the circuit layer electrically connect with the electrodes. Except for the above-described electrical connection manner, the present invention also provides other methods for electrically connecting the circuit layer to the electrodes and protecting the bumps from damage. For example, a heat pressing method or an ultrasonic bonding method can be used to electrically connect the bumps and the electrodes directly. In addition, the present invention takes advantages of capillarity for a non-conductive material to be adhered to the bump surfaces and a partial surface of the LED chip, which protects the bumps and the LED chip from the damage caused by the external environment. The non-conductive material can be resin.

As an option, the present invention allows to use a non-conductive adhesive to substitute the above-mentioned conductive adhesive, wherein the bumps press the non-conductive adhesive for electrically connecting the electrodes. In more detail, the electrical connection between the bumps and the electrodes is achieved by the heat pressing method or the ultrasonic bonding method. Note that the non-conductive adhesive can be pressed by the bumps and then adhered to the partial surfaces of the bumps, which also protects the bumps from damage. The material of the non-conductive adhesive is, for example, B-stage adhesive.

Note that with the increase in the integrity and the operation power of a semiconductor device, the heat amount per unit area of a semiconductor device is accordingly increased. To solve the above-mentioned thermal issue, the LED package 100 in the embodiment uses a heat sink 150 for facilitating heat dissipation of the LED chip 110. The heat sink 150 is adhered to the back surface 122b of the flexible substrate 122, wherein a heat-conductive adhesive can be used and connected between the back surface 122b and the heat sink 150. Thus, the heat generated by the LED chip 110 can be conducted to the heat sink 150 and the internal temperature of the LED chip 110 is reduced. For better heat dissipation efficiency, a plurality of thermal vias (not shown) may be made on the flexible substrate 120 and located in the area covered by the heat sink 150, wherein the thermal vias are filled with metal or other heat conductive materials to increase the heat dissipation efficiency of the LED chip 110.

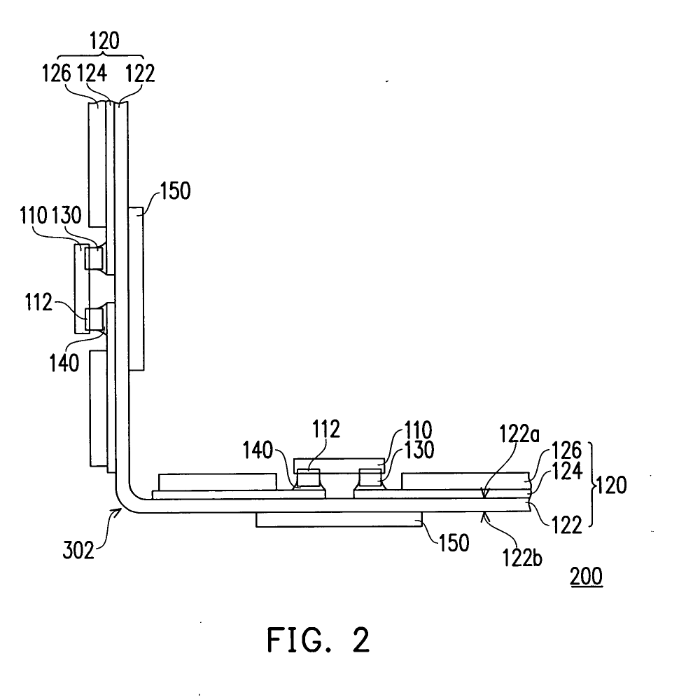

FIG. 2 is a diagram of a LED package provided by the second embodiment of the present invention. The LED package 200 in FIG. 2 is similar to the LED package 100 of the first embodiment except that the LED package 200 includes two LED chips 110 and has a bending area 202. In other words, the LED package 200 of the present embodiment has substantially equally good yieldingness. In the embodiment, the bending area 202 of the LED package 200 provides the LED chips 110 with different positions on the flexible carrier 120. For example, the two LED chips 110 can be disposed at both sides of the bending area 202, respectively, wherein the bending area 202 can be formed by bending the flexible carrier 120. Note that when the two LED chips 110 are disposed at both sides of the bending area 202, respectively, the two LED chips 110 have different light emitting directions.

Accordingly, when the LED package 200 is disposed in an electronic product (not shown), the LED package 200 can be adjusted to have an appropriate shape to meet the space design requirement inside the electronic product and further to have different light emitting directions. In this way, the practicality of the LED package 200 in electronic product applications is significantly increased.

The present invention does not limit the positions of a LED chip on a flexible carrier, or limit the quantity and positions of heat sinks on the flexible carrier. In the above-described embodiment, the LED package with two LED chips and a bending area is only exemplary. In fact, the present invention does not limit the quantity of the LED chips and the bending area of the flexible carrier in a LED package. Compared with the prior art, the LED package of the present invention possesses good yieldingness to make the LED chips have different light emitting directions by adjusting the flexible carrier freely. Accordingly, the application fields of the LED package provided by the present invention are further expanded.

It will be apparent to those skilled in the art that various modifications and variations can be made to the structure of the present invention without departing from the scope or spirit of the invention. In view of the foregoing, it is intended that the specification and examples to be considered as exemplary only, with a true scope and spirit of the invention being indicated by the following claims and their equivalents.

What is claimed is:

1. A light emitting diode package (LED package), comprising:
a LED chip, having a plurality of electrodes; and
a flexible carrier, having a flexible substrate and a circuit layer, wherein the flexible substrate has a support surface and a back surface opposite the support surface, the circuit layer is disposed on the support surface and the electrodes of the LED chip are electrically connected to the circuit layer of the flexible carrier.

2. The LED package as recited in claim 1, wherein the flexible carrier further comprises a solder mask layer disposed on the circuit layer and the solder mask layer exposes the circuit layer electrically connected to the electrodes.

3. The LED package as recited in claim 1, further comprising a plurality of bumps disposed on the electrodes, wherein the circuit layer is electrically connected to the electrodes through the bumps.

4. The LED package as recited in claim 3, wherein the bumps comprise gold bumps, copper bumps, nickel bumps or aluminum bumps.

5. The LED package as recited in claim 3, wherein a material of the bump is conductive B-stage adhesive.

6. The LED package as recited in claim 3, further comprising a plurality of conductive materials, wherein the conductive materials are disposed between the circuit layer and the bumps such that the circuit layer is electrically connected to the bumps through the conductive materials.

7. The LED package as recited in claim 6, wherein the conductive material comprises solder, conductive B-stage adhesive, anisotropic conductive film (ACF) or anisotropic conductive paste (ACP).

8. The LED package as recited in claim 1, wherein the flexible carrier comprises a flexible printed circuit board (FPCB).

9. The LED package as recited in claim 1, wherein a material of the flexible substrate comprises polyimide (PI).

10. The LED package as recited in claim 1, further comprising a heat sink adhered to the back surface.

11. The LED package as recited in claim 10, wherein the flexible substrate has a plurality of thermal vias filled with metal and the thermal vias are located in the area covered by the heat sink.

12. The LED package as recited in claim 1, wherein a material of the circuit layer comprises copper.
